(19) United States
(12) Patent Application Publication
(10) Pub. No.: US 2015/0021166 A1
(43) Pub. Date: Jan. 22, 2015

(54) SPUTTERING APPARATUS AND METHOD

(71) Applicants: Evelyn Scheer, Stockstadt (DE); Oliver Graw, Alzenau (DE)

(72) Inventors: Evelyn Scheer, Stockstadt (DE); Oliver Graw, Alzenau (DE)

(73) Assignee: APPLIED MATERIALS, INC., Santa Clara, CA (US)

(21) Appl. No.: 14/238,129

(22) PCT Filed: Aug. 25, 2011
(86) PCT No.: PCT/EP2011/064668

§ 371 Date: Sep. 22, 2014

(51) Int. Cl. H01J 37/34

(52) U.S. Cl. CPC H01J 37/3417; H01J 37/3435
USPC 204/192.12; 204/298.12

(57) ABSTRACT

A deposition apparatus for depositing a layer of deposition material on a substrate is provided. The apparatus includes a substrate support adapted for holding the substrate; a target support (520) adapted for holding a target assembly. The target assembly includes a backing element and at least two target elements (510, 511) arranged on the backing element next to each other so that a gap (530) is formed between the at least two target elements. The gap between the target elements is to have a width (w). Further, the substrate support and the target support are arranged with respect to each other so that the ratio of distance between substrate and target (570) element to the gap width (w) is about 150 and greater.

### TECHNICAL FIELD OF THE INVENTION

Embodiments of the present invention relate to a deposition apparatus and a method of forming a layer of deposition material on a substrate. Embodiments of the present invention particularly relate to a deposition apparatus having a multi-tile target support, and a method for positioning a target.

### BACKGROUND OF THE INVENTION

Several methods are known for depositing a material on a substrate. For instance, substrates may be coated by a physical vapor deposition (PVD) process, such as a sputter process. Other deposition processes include chemical vapor deposition (CVD), a plasma enhanced chemical vapor deposition (PECVD) etc. Typically, the process is performed in a process apparatus or process chamber, where the substrate to be coated is located. A deposition material is provided in the apparatus. In the case where a PVD process is performed, the deposition material may for instance be in the gaseous phase. A plurality of materials may be used for deposition on a substrate; among them, ceramics can be used. Typically, a PVD process is suitable for thin film coatings.

Coated materials may be used in several applications and in several technical fields. For instance, an application lies in the field of microelectronics, such as generating semiconductor devices. Also, substrates for displays are often coated by a PVD process. Further applications may include insulating panels, organic light emitting diode (OLED) panels, but also hard disks, CDs, DVDs and the like.

Substrates are arranged in or guided through a deposition chamber for performing the coating process. The deposition chamber provides a target on which the material to be deposited on the substrate is arranged. In some applications, it is required to deposit material layers on large substrates. In this case, also the corresponding components of a deposition chamber are adapted to the size of the substrate. For instance, the size of the target is chosen according to the substrate size in order to provide proper deposition over the whole area of the substrate.

One piece targets are used for large substrates for ensuring a uniform layer deposition over the substrate. However, one piece targets having the required size for large substrates are expensive and difficult to manufacture and handle. Further, one piece targets are error-prone due to the extension of the deposition material over the whole length of the target. Further, it is known to use targets having several tiles of deposition material thereon. These multi-tile targets are not as cost intensive as the one piece targets, but often the pattern of the tiles on the target creates a pattern in the deposition layer of the substrate.

In view of the above, it is an objective of the present invention to provide a deposition apparatus, particularly a deposition apparatus for a multi-tile target, and a method of forming a deposition layer with a multi-tile target that will overcome at least some of the problems in the art.

### SUMMARY OF THE INVENTION

In light of the above, an apparatus for forming a deposition material layer according to independent claim 1 and a method for depositing a layer according to independent claim 12 are provided. Further aspects, advantages, and features of the present invention are apparent from the dependent claims, the description, and the accompanying drawings.

According to one embodiment, a deposition apparatus for depositing a layer on a substrate is provided. The deposition apparatus includes a substrate support adapted for holding the substrate and a target support. The target support is adapted for holding a target assembly. The target assembly includes a backing element and at least two target elements arranged on the backing element next to each other. A gap is formed between the at least two target elements. The gap being adapted to have a width w and the substrate support and/or the target support are arranged with respect to each other so that the ratio of distance between substrate and target element to gap width w is at least about 150.

According to another embodiment, a method for forming a layer on a substrate in a deposition apparatus is provided. The method includes providing a substrate to be coated; providing a target assembly including a backing element and at least two target elements on the backing element next to each other. A gap is formed between the at least two target elements and the gap has a width w. Further, the method includes positioning the substrate relative to the target assembly so that the ratio of the distance between substrate and target element to gap width w is at least about 150.

Embodiments are also directed at apparatuses for carrying out the disclosed methods and include apparatus parts for performing each described method step. These method steps may be performed by way of hardware components, a computer programmed by appropriate software, by any combination of the two or in any other manner. Furthermore, embodiments according to the invention are also directed at methods by which the described apparatus operates. It includes method steps for carrying out every function of the apparatus.

### BRIEF DESCRIPTION OF THE DRAWINGS

So that the manner in which the above recited features of the present invention can be understood in detail, a more particular description of the invention, briefly summarized above, may be had by reference to embodiments. The accompanying drawings relate to embodiments of the invention and are described in the following:

FIG. 1 shows a schematic view of a deposition chamber according to embodiments described herein;

FIG. 2 shows a schematic view of a deposition material distribution according to embodiments described herein;

FIG. 3 shows a schematic view of a deposition material distribution according to embodiments described herein;

FIG. 4 shows a schematic view of a multi-tile target as used in a deposition chamber according to embodiments described herein;

FIG. 5 shows a schematic view of a multi-tile target as used in a deposition chamber according to embodiments described herein; and

FIG. 6 shows a schematic flow chart of a method for depositing a layer on a substrate according to embodiments described herein.

### DETAILED DESCRIPTION OF EMBODIMENTS

Reference will now be made in detail to the various embodiments of the invention, one or more examples of which are illustrated in the figures. Within the following description of the drawings, the same reference numbers refer to the same components. Generally, only the differences with respect to individual embodiments are described. Each example is provided by way of explanation of the invention and is not meant as a limitation of the invention. Further, features illustrated or described as part of one embodiment can be used on or in conjunction with other embodiments to yield yet a further embodiment. It is intended that the description includes such modifications and variations.

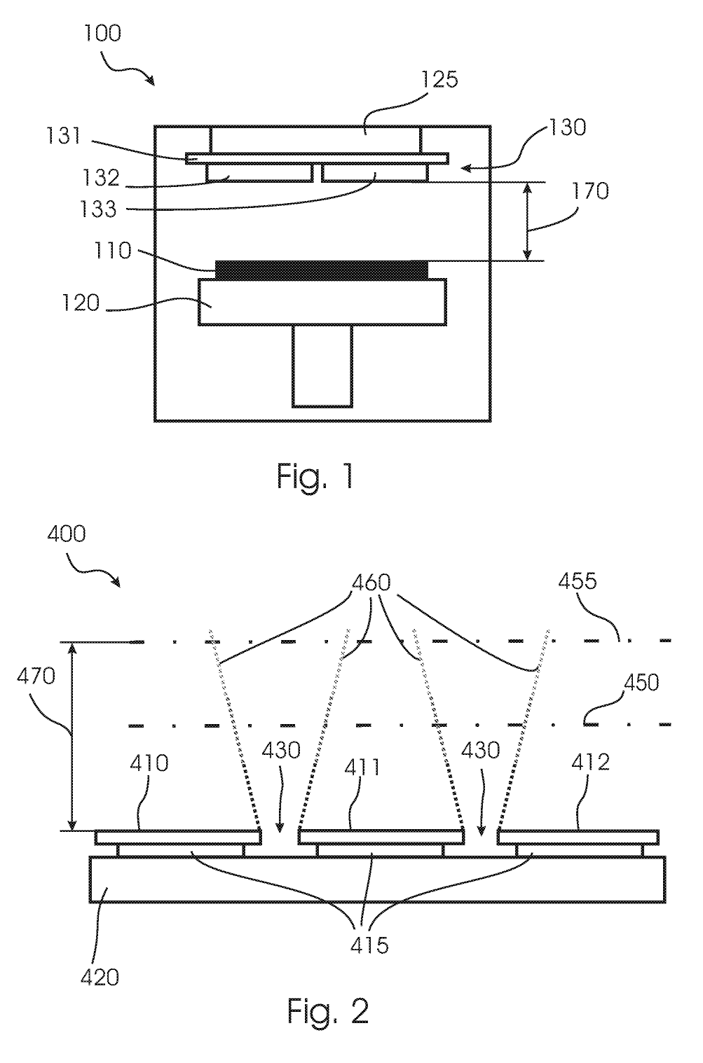

FIG. 1 shows a schematic view of a deposition chamber 100 according to embodiments. The deposition chamber 100 is adapted for a deposition process, such as a PVD process. A substrate 110 is shown being located on a substrate support 120. According to some embodiments, the substrate support may be movable to allow adjusting the position of the substrate 110 in the chamber 100. Typically, the substrate support 120 may be movable in order to allow for uniform layer deposition, for instance, by rotation. A target support 125 is provided in chamber 100. The target support 125 is adapted for holding a target assembly 130. Typically, the target assembly 130 provides the material to be deposited on substrate 110.

According to some embodiments, the target assembly 130 may include a backing element 131, as can be seen in FIG. 1. Typically, the backing element 131 is adapted to carry target elements 132 and 133. The target elements may provide the material to be deposited. A target assembly having more than one target element is also denoted as multi-tile target assembly.

According to some embodiments, large area substrates may have a size of typically about 1.4 m2 to about 8 m2, more typically about 2 m2 to about 9 m² or even up to 12 m². Typically, the rectangular substrates for which the mask structures, apparatuses, and methods according to embodiments described herein are provided are large area substrates as described herein. For instance, a large area substrate can be GEN 5, which corresponds to about 1.4 m2 substrates (1.1 m×1.25 m), GEN 7.5, which corresponds to about 4.29 m2 substrates (1.95 m×2.2 m), GEN 8.5, which corresponds to about 5.7 m² substrates (2.2 m×2.5 m), or even GEN 10, which corresponds to about 8.7 m2 substrates (2.85 m×3.05 m). Even larger generations such as GEN 11 and GEN 12 and corresponding substrate areas can similarly be implemented.

Typically, a substrate may be made from any material suitable for material deposition. For instance, the substrate may be made from a material selected from the group consisting of glass (for instance soda-lime glass, borosilicate glass etc.), metal, polymer, ceramic, compound materials, carbon fiber materials or any other material or combination of materials which can be coated by a deposition process.

In the case that thin film transistors (TFTs) are produced, metal oxides such as indium gallium zinc oxide (IGZO) recently became a popular candidate as material to be deposited. Metal oxides may replace amorphous silicon as the active layer of thin film transistors for applications in next generation display technologies mainly because of their high mobility and transparency. A typical method to produce such metal oxide layers is a partial reactive PVD process from a bonded, ceramic target on large-area coaters. Exemplarily, the deposition apparatus of embodiments described herein may be adapted for performing a partial reactive PVD process from a bonded, ceramic target.

Since the manufacture of targets providing ceramics as deposition material (e.g. manufacture by sintering of ceramics) is especially challenging for long cylinders and plates it is common to put several cylinders or plates together for one large size target, which may be a sputter target.

In FIG. 1, exemplarily two target elements 132 and 133 are shown. According to some embodiments, which can be combined with other embodiments described herein, the number of target elements may typically be greater than two, such as four, five, ten or even twenty. Typically, the number of target elements depends on the process, the substrate size, the deposition material, the target design and further parameters. As an example, the number of target elements of a tube target may be about 13 to 14 target elements for a target of GEN 8.5, i.e. a target for a substrate size of about 5.7 m². According to embodiments, the number of target elements of a planar target of GEN 8.5 may be about three to four target elements. The number of target elements may be chosen according to process parameters and may deviate from the number exemplarily described herein.

Generally, a gap is formed between target elements. Typically, the gap is provided between the target elements for allowing thermal expansion during operation. For instance, when indium is used to bond the target elements to the backing element of the target assembly, space is provided by the gap for allowing the thermal expansion.

In deposition systems, the arrangement of multi-tile target assemblies influences the deposition characteristic on the substrate. A visible mura effect appears in the finished product when multi-tile target assemblies are used. The mura effect can be described as the appearance of stripes, which indicates an irregularity in at least one of the layers deposited on the substrate. Typically, the stripes show up in a finished product such as a display. In the case that an OLED or LCD panel driven by a metal oxide TFT backplane is being produced, the mura effect may cause failure of the function of the OLED or LCD panel in some areas of the panel.

It is known to use one piece targets to avoid the need for multi-tile targets; however, one-piece targets increase the costs for the target manufacturing and target handling. Multi-tile targets are not as cost intensive as the one piece targets, but often cause the above described mura effect.

Typically, the gaps between the target elements may be responsible for generating the mura effect. According to embodiments described herein, the mura pattern, i.e. the stripes on the substrate indicating an irregularity in the deposited material, can be traced back to the gap location and geometry.

Thus, in known systems, the regularity of the deposition material on the substrate is influenced by the gap between the target elements. In systems according to embodiments described herein, the regularity of the deposition material on the substrate is substantially independent from the gap between the target elements, i.e. the gap does not have a substantial influence on the regularity and uniformity of the layer of deposition material on the substrate.

The term “substantially independent from the gap” should be understood in that no mura effect due to the gaps between the target elements can be seen on the layer deposited on the substrate.

FIG. 2 shows a plate or tube target assembly 400 having a backing element 420 and exemplarily three target elements 410, 411, and 412. According to some embodiments, the number of target elements, the material used for the target assembly and the bonding between the backing element and the target elements may be the same as described with respect to FIG. 1. In the embodiment shown in FIG. 2, the bonding material 415, which bonds the target elements to the backing element of the target assembly 400, can be seen. Gaps 430 are formed between the target elements.

In FIG. 2, line 450 indicates a plane of the substrate surface in a deposition apparatus as known in the art. The influence of the gaps is high in plane 450. This can be seen in FIG. 2 by dashed lines 460.

Generally, lines 460 extend from the gaps 430 indicating schematically the influence of the gap on the deposition material released from the target elements. Typically, the influence of the gaps weakens with increasing distance from the target elements, which is indicated by the fading color of dashed lines 460. Further, the dashed lines 460 indicate the region of gap influence spreading in a direction substantially parallel to the substrate surface.

Typically, the influence of the gaps shown by lines 460 is reduced with increasing distance from the target elements. The increased interaction of particles released from the target elements may cause the reduced influence of the gap. According to some embodiments, the distance between the target element and the substrate surface in plane 455 allows for more spreading, collision and diffusion of the particles released from the target elements on the way to the substrate than the distance between the target element and the substrate surface in plane 450.

According to embodiments described herein, the distance between the target elements 410, 411, and 412 and the plane 455 of the substrate surface allows for overcoming and substantially avoiding the mura effect. As an example, for a gap of about 0.5 mm, a target-substrate-distance 470 of at least about 75 mm overcomes the mura effect in a metal oxide deposition process.

According to some embodiments, the target-substrate-distance is typically between about 75 mm to about 350 mm, more typically between about 100 mm and about 300 mm, and even more typically about 200 mm.

Generally, the term “target-substrate-distance” should be understood as the distance between the surface of the substrate to be coated and the surface of at least one target element before a deposition process takes place.

Typically, the ratio of the distance between the substrate and the target element to the gap width is about 150 and greater, preferably between about 400 and 600. According to some embodiments, the ratio may be slightly below 150, such as 145 or 140. According to other embodiments, the ratio may also be above 600, such as 610 or even 630. According to some embodiments, arranging the target-substrate-distance depending on the gap width with a ratio of at least about 150 enables creating metal oxide layers for mura-free panels with a cost efficient multi-tile target approach.

Referring back to FIG. 1, the target-substrate-distance is indicated by reference number 170. Although the schematic drawings herein may show ratios differing from the ratio according to embodiments described herein, the ratio of the distance between the substrate and the target element to the gap width should nevertheless be understood as being at last about 150, preferably between about 400 and 600, unless otherwise stated.

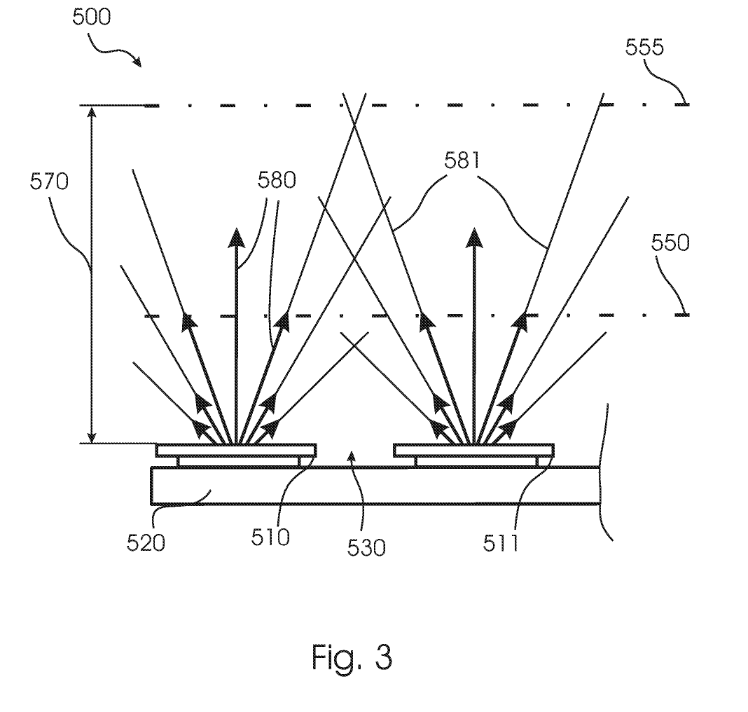

FIG. 3 shows exemplarily the distribution of released particles as arrows 580. For the sake of lucidity, only two arrows are indicated with reference number 580. A section of a target assembly 500 having a backing element 520 and several target elements is shown in FIG. 3. In the section of the target assembly 500, two target elements 510 and 511 are exemplarily shown.

Typically, the distribution field of deposition material can be understood as including substantially all particles released from the target element. In FIG. 3, arrows 580 denote the direction of the released particles of the target elements. For instance, the distribution field of deposition material of target element 510 includes all arrows 580 originating from the target element 510. According to some embodiments, the distribution field may have substantially the shape of a cosine function. The length of arrows 580 indicates approximately the number of particles released in the direction of the arrow. For instance, the arrow going straight upwards present the direction of a defined number of released particles, whereas the arrow to the left or right of the straight arrow presents a smaller number of particles.

According to some embodiments, the target-substrate-distance 570, as shown in FIG. 3, from the target elements 510 and 511 to the plane 555 of the substrate surface satisfies the above discussed ratio of the distance between substrate and target element to the gap width, i.e. satisfies the ratio of at least about 150.

Typically, with satisfying the ratio, more particle collisions are possible and particle distribution is extended, which can be seen in FIG. 3 due to extensions 581 of the arrows 580. Again, only two extensions are indicated with reference number 581 for the sake of lucidity. The extensions 581 of arrows 580 indicate the direction in which the particles released in the direction of arrows 580 will proceed. The extensions 581 of arrows 580 of target element 510 overlap at some point with the extensions 581 of the arrows of the target element 511 next to target element 510.

According to some embodiments, the overlapping of extensions means that the collision, spread and distribution of released particles is increased and the influence of the gap between the target elements is decreased.

In FIG. 3, line 555 indicates a target-substrate-distance having a ratio to the gap width of at least about 150 according to embodiments described herein. Almost all extensions 581 of arrows 580 cross before reaching line 555. That is, the distribution fields of deposition material of the target elements overlap substantially with each other.

In this context, the term “overlap substantially” should be understood in that large parts of the distribution fields intersect and interact with each other before reaching the plane of the substrate surface, i.e. the surface to be coated. For instance, the particles released in an angle of less than 90° from the target element surface interact with the particles released in an angle of less than 90° from an adjacent target element surface. As an example, all arrows of FIG. 3 intersect with the arrows of the adjacent target element, except the one being at substantially 90° to the target element surface.

The term “substantially” in this context means that there may be a certain deviation from the characteristic denoted with “substantially.” For instance, “substantially 90°” may include deviations of typically about 1° to 10°, more typically from about 2° to about 8°, and even more typically from about 3° to about 7°.

According to some embodiments, the line 555 in FIG. 3 provides a target-substrate-distance satisfying a ratio of at least about 150 to the gap width. In contrast thereto, line 550 indicates a target-substrate-distance used in known deposition apparatus, which does not satisfy the ratio of at least 150. Thus, a deposition process of a substrate being located approximately in the region of line 550 may lead to the mura effect described above, showing the influence of the gap between the target elements. For instance, the distance between the target and line 550 may be 60 mm or less, as known in the art.

Typically, a substrate located at a target-substrate-distance 570 satisfying the ratio according to embodiments described herein, may have a regular layer of deposition material over the whole substrate area.

In this context, a “regular” deposition should be understood as being a deposition, which is substantially uniform over the substrate surface. In particular, “regular” in this context means free of mura effects, i.e. stripes on the substrate. According to some embodiments, the stripes of the mura effect may indicate an irregularity in a deposition characteristics, such as—but not limited to—the energy with which the released particles hit the substrate, the layer density, the material composition, the local layer structure, oxygen content and the like.

According to some embodiments, the target support and the substrate support of a deposition chamber may be adapted to be movable with respect to each other. For instance, the target support and/or the substrate support may be adapted to adjust the distance between the substrate surface and the target elements. Typically, the distance between the substrate surface and the target elements of the target assembly may be adjusted dependent on the gap between the target elements of the target assembly before using the target assembly in a deposition process.

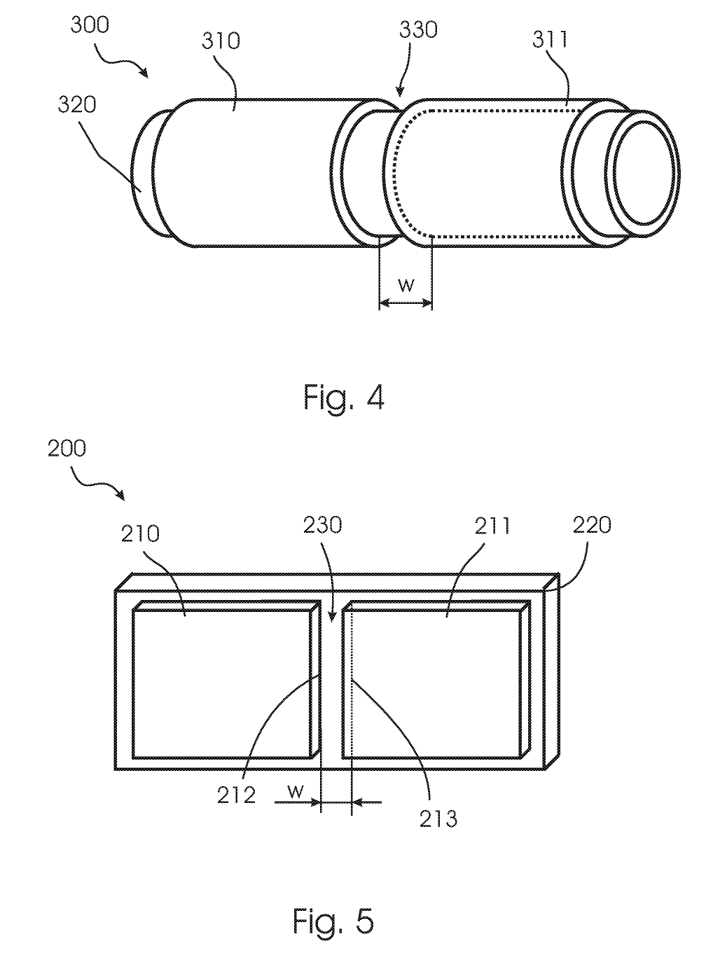

FIG. 4 shows a target plate assembly 200 as may be used in embodiments described herein. The target assembly 200 is a target plate in FIG. 4 having exemplarily two target elements 210 and 211 on a backing element 220. The number of target elements, the material of the target elements and the bonding of the target elements to the backing element 220 may be chosen as described above with respect to FIG. 1.

Typically, the target elements may be target tiles. Target tiles may be pieces of material to be deposited having a defined geometry. According to some embodiments, the target elements may be bonded to the backing element by a bonding material, such as a soldering metal. Typically, the soldering metal may include indium or the like.

According to some embodiments, the material to be deposited may be chosen according to the deposition process and the later application of the coated substrate. For instance, the deposition material of the target may be ceramics. Typically, the target material may be an oxide ceramic, more typically, the material may be a ceramic selected from the group consisting of an indium containing ceramic, a tin containing ceramic, a zinc containing ceramic and combinations thereof. According to some embodiments, the material to be deposited may also be selected from the group consisting of: indium-, tin-, zinc-, gallium-containing oxides, nitrides and oxynitrides. Typically, the material of the target elements may be indium gallium zinc oxide (IGZO), indium tin oxide (ITO), zinc tin oxide (ZTO), indium zinc oxide (IZO) or the like.

Typically, a gap is formed between the target elements. In FIG. 4, the gap between the target elements 210 and 211 is denoted with reference number 230. Typically, the gap 230 has a width w as can be seen in FIG. 4. The gap between the target elements reaches from one edge of one target element to one facing edge of an adjacent target element.

In FIG. 4, the gap 230 reaches from the edge 212 of target element 210 to edge 213 of target element 211. Typically, the edges of the target elements used for defining the gap are the edges of the target elements on the side, which is bonded to the backing element.

According to some embodiments, the width of the gap described herein is the width before using the target elements in a deposition process. In other words, the gap width w is defined as the gap between the target elements after mounting the target elements to the backing plate, but before or immediately after mounting the target assembly in the deposition apparatus. For instance, the gap width w may be the distance between the target elements at the standard conditions of temperature and pressure, e.g. ISO 5011.

According to some embodiments, the backing element of the target assembly may be a tube or may have a cylinder-like shape. Typically, the target support and the target assembly may be adapted to be rotatable.

FIG. 5 shows a target assembly 300 according to embodiments described herein. Typically, the backing element 320 is a tube, to which target elements 310 and 311 are bonded. According to some embodiments, the number of target elements, the material used for the target assembly and the bonding between the backing element and the target elements may be the same as described with respect to FIG. 1. Also in FIG. 5, the gap 330 between the target elements 310 and 311 can be seen having a width w. The gap is measured from one edge of one target element to the facing edge of an adjacent target element. Typically, the edges of the target elements used for determining the gap width w are on the side, which is bonded to the backing element.

Typically, the gap width may be between about 0.2 mm and about 0.7 mm, more typically between about 0.3 mm and about 0.6 mm, and even more typically between about 0.3 mm and about 0.5 mm.

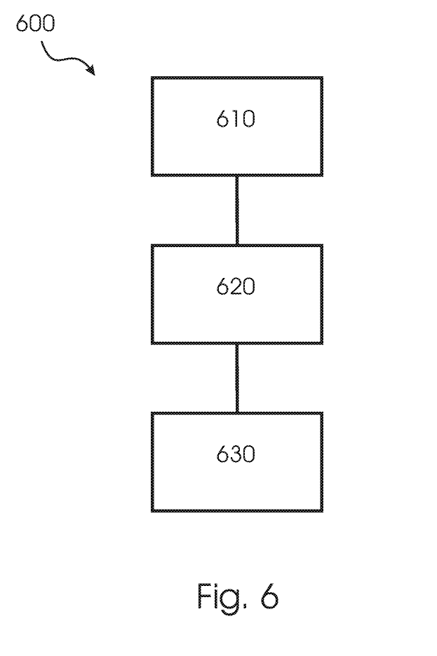

According to some embodiments, a method is provided for forming a layer of deposition material on a substrate. FIG. 6 shows a flow chart 600 of a method according to embodiments described herein. The deposition process for generating a layer on a substrate may be performed in a deposition chamber, which may exemplarily be a deposition chamber as shown in and described with respect to FIG. 1.

Typically, a substrate is provided in step 610. The substrate may be a substrate as described with respect to FIG. 1 and may be suitable for a deposition process such as PVD or the like. According to some embodiments, the substrate may be a large area substrate having an area of about 1.4 m² to about 8.7 m², more typically about 2 m² to about 6 m², and even more typically about 4.3 m² and 5.7 m², as also described with respect to FIG. 1. Typically, the substrate may be provided by guiding it in a deposition chamber, by driving a substrate support in a deposition chamber, or the like.

In step 620 of FIG. 6, a target assembly is provided for delivering the material to be deposited on the substrate. According to embodiments described herein, the target assembly includes a backing element on which target elements are arranged. Typically, the backing element may have a shape suitable for the deposition process and may be chosen according to the substrate to be coated. According to some embodiments, the backing element may have the shape of a plate or a tube. The target elements are substantially made of the material to be deposited. Typically, the target elements may be tiles of deposition material. Between the target elements, a gap is formed having a width w.

Step 630 denotes positioning the substrate and the target assembly relative to each other dependent on the gap of the target element of the target assembly. The target and/or the substrate are positioned so that the ratio of the distance between substrate and target element to the gap width w is at least about 150. Typically, the ratio may be between about 400 and about 600. According to some embodiments, the ratio may be slightly below 150, such as 145 or 140. According to other embodiments, the ratio may be above 600, such as 620 or even 630.

Typically, the width of the gap between the target elements is defined as reaching from one edge of one target element to a corresponding edge of an adjacent target element. The width w can be understood by referring to the FIGS. 4 and 5 and the description thereof.

According to some embodiments, the substrate and/or the target are positioned so that the distance between the substrate surface and the target surface is typically from about 75 mm to about 350 mm, more typically between about 100 mm and about 300 mm, and even more typically about 200 mm.

Generally, the target elements have a distribution field of deposition material. The distribution field has a defined characteristic of the distribution of particles released from the target elements. The distribution field should be understood as the area or region in which the released particles of the target elements are distributed. Typically, the distribution field may have substantially a cosine shape.

According to some embodiments, the distribution fields of adjacent target elements may substantially overlap in the plane of the substrate surface. The term “substantially overlap” should be understood as described with respect to FIG. 3. Overlapping distribution fields of the deposition material enable a regular deposition material layer on the substrate. The substrate and the target being arranged according to embodiments described herein allow for more particle collision and particle interaction so that the deposition on the substrate becomes uniform. In particular, the influence of the gap on the uniformity of the layer is at least decreased, or even substantially avoided.

In view of the above, several embodiments can be described. According to one aspect described herein, a deposition apparatus for depositing a layer of deposition material on a substrate is provided. The apparatus includes a substrate support adapted for holding the substrate and a target support adapted for holding a target assembly. The target assembly includes a backing element and at least two target elements arranged on the backing element next to each other so that a gap is formed between the at least two target elements. The gap between the target elements is to have a width w. Further, the substrate support and the target support are arranged with respect to each other so that the ratio of distance between substrate and target element to the gap width w is at least about 150. Typically, the ratio of the distance (470; 570) between substrate and target element to the gap width w can be between about 400 and about 600. According to further embodiments, the distance between the substrate and the target element can be about 75 mm or above. According to some embodiments, the gap width between the at least two target elements can be defined as reaching from the edge of a first target element to a facing edge of a second target element. According to further embodiments, the distance between the substrate support and the target support can be adapted to allow the distribution fields of deposition material of the single target elements to substantially overlap in the plane of the substrate surface so as to provide a regular deposition on the substrate. Typically the regularity of the deposition on the substrate can be is substantially independent of the gap between the target elements. According to some embodiments, the distance between the substrate support and the target support can be adapted so that a bond gap mura generation is substantially avoided. Typically, the backing element of the target assembly can be a plate or a tube. According to some embodiments the target elements can include an oxide ceramic. According to an aspect of embodiments described herein, the substrate support can be adapted for holding a substrate of about 1.5 m² or above. Typically, the target support can be adapted to hold a rotatable target assembly.

According to a further aspect, a method for forming a layer of deposition material on a substrate in a deposition apparatus is provided. The method includes providing a substrate to be coated; and providing a target assembly having at least two target elements on a backing element next to each other so that a gap is formed between the at least two target elements. Typically, the gap has a width w. The method further includes positioning the substrate relative to the target assembly so that the ratio of the distance between substrate and target to the gap width w is at least about 150. According to some embodiments, the gap between the at least two target elements can be defined as reaching from the edge of a first target element to a facing edge of a second target element. Typically, positioning the substrate can include positioning the substrate in a distance of about 75 mm or above from the target. According to some embodiments, positioning the substrate can further include positioning the substrate relative to the target assembly so as to allow the distribution fields of deposition material of the single target elements to overlap in the plane of the substrate surface so as to provide a regular deposition on the substrate.

While the foregoing is directed to embodiments of the invention, other and further embodiments of the invention may be devised without departing from the basic scope thereof, and the scope thereof is determined by the claims that follow.

1. Deposition apparatus for depositing a layer of deposition material on a substrate, the apparatus comprising:
a substrate support adapted for holding the substrate;
a target support adapted for holding a target assembly, the target assembly comprising a backing element; and
at least two target elements arranged on the backing element next to each other so that a gap is formed between the at least two target elements, the gap being adapted to have a width w, wherein the substrate support and the target support are arranged with respect to each other so that the ratio of distance between the substrate and the target element to the gap width w is at least about 150.

2. The deposition apparatus according to claim 1, wherein the ratio of distance between substrate and target element to the gap width w is between about 400 and about 600.

3. The deposition apparatus according to claim 1, wherein the distance between substrate and target element is about 75 mm or above.

4. The deposition apparatus according to claim 2, wherein the gap width between the at least two target elements is defined as reaching from the edge of a first target element to a facing edge of a second target element.

5. The deposition apparatus according to claim 2, wherein the distance between the substrate support and the target support (125) is adapted to allow the distribution fields of deposition material of the single target elements to substantially overlap in the plane of the substrate surface so as to provide a regular deposition on the substrate.

6. The deposition apparatus according to claim 1, wherein the distance between the substrate support and the target support is adapted so that a bond gap mura generation is substantially avoided.

7. The deposition apparatus according to claim 1, wherein the backing element is a plate.

8. The deposition apparatus according to claim 1, wherein the backing element is a tube.

9. The deposition apparatus according to claim 1, wherein the target elements comprise an oxide ceramic, preferably a ceramic selected from the group consisting of an indium containing ceramic, a tin containing ceramic, a zinc containing ceramic and combinations thereof, such as indium gallium zinc oxide (IGZO), indium tin oxide (ITO), zinc tin oxide (ZTO), and indium zinc oxide (IZO).

10. The deposition apparatus according to claim 1, wherein the substrate support is adapted for holding a substrate of about 1.5 m² or above.

11. The deposition apparatus according to claim 1, wherein the target support is adapted to hold a rotatable target assembly.

12. Method for forming a layer of deposition material on a substrate in a deposition apparatus, comprising:
providing a substrate to be coated;
providing a target assembly comprising at least two target elements on a backing element next to each other so that a gap is formed between the at least two target elements, wherein the gap has a width w; and
positioning the substrate relative to the target assembly so that the ratio of the distance between the substrate and the target element to the gap width w is at least about 150.

13. The method according to claim 12, wherein the gap between the at least two target elements is defined as reaching from the edge of a first target element to a facing edge of a second target element.

14. The method according to claim 12, wherein positioning the substrate comprises positioning the substrate in a distance of about 75 mm or above from the target elements.

15. The method according to claim 12, wherein positioning the substrate further comprises positioning the substrate relative to the target assembly so as to allow the distribution fields of deposition material of the single target elements to overlap in the plane of the substrate surface so as to provide a regular deposition on the substrate.

16. The deposition apparatus according to claim 2, wherein the distance between substrate and target element is about 75 mm or above.

17. The deposition apparatus according to claim 1, wherein the gap width between the at least two target elements is defined as reaching from the edge of a first target element to a facing edge of a second target element.

18. The deposition apparatus according to claim 1, wherein the distance between the substrate support and the target support is adapted to allow the distribution fields of deposition material of the single target elements to substantially overlap in the plane of the substrate surface so as to provide a regular deposition on the substrate.

19. The method according to claim 13, wherein positioning the substrate comprises positioning the substrate in a distance of about 75 mm or above from the target elements.

20. Deposition apparatus for depositing a layer of deposition material on a substrate, the apparatus comprising:
a substrate support adapted for holding the substrate; and
a target assembly, the target assembly comprising a backing element and at least two target elements providing the material to be deposited and being arranged on the backing element next to each other so that a gap of 0.5 mm or less is formed between the at least two target elements, wherein the distance of the substrate support and at least one of the two target elements is about 75 mm or more.
